(19) United States
(12) Patent Application Publication
(10) Pub. No.: US 2025/0230747 A1
(43) Pub. Date: Jul. 17, 2025

(54) NOVEL 3D PORE SURFACE ROUGHNESS QUANTIFICATION TECHNOLOGY FOR POROUS MEDIA

(71) Applicants: SAUDI ARABIAN OIL COMPANY, Dhahran (SA); King Abdullah University of Science and Technology, Thuwal-Jeddah (SA)

(72) Inventors: Xupeng He, Dhahran (SA); Yiteng Li, Thuwal (SA); Marwah Mufid AlSinan, Al Qatif (SA); Jun Gao, Dhahran (SA); Hyung Tae Kwak, Dhahran (SA); Hussein Hoteit, Thuwal (SA)

(73) Assignees: SAUDI ARABIAN OIL COMPANY, Dhahran (SA); King Abdullah University of Science and Technology, Thuwal-Jeddah (SA)

(21) Appl. No.: 18/410,599

(22) Filed: Jan. 11, 2024

(51) Int. Cl. E21B 49/00; G01V 11/00; G06T 7/40; G06T 17/20

(52) U.S. Cl. CPC E21B 49/00; G01V 11/002; G06T 7/40; G06T 17/20; E21B 2200/20; G06T 2207/10028; G06T 2207/10081; G06T 2207/30181

(57) ABSTRACT

Methods and systems for a novel three-dimensional (“3D”) pore roughness quantification are disclosed. The methods include obtaining an image of a pore space. The methods further include, using an image analysis system: discretizing the 3D image to generate a meshed surface; constructing a reference surface and a constructed surface from the meshed surface; evaluating a plurality of surface distances; and determining a roughness coefficient. The methods further include obtaining an observed T2 time for at least one sample depth in a well; determining a corrected T2 time from the observed T2 time; and determining an average pore size in a rock formation.

### BACKGROUND

Nuclear Magnetic Resonance (NMR) is a logging tool for measuring the petrophysical properties of reservoir rocks. One of its important applications is to evaluate the pore size distribution by assuming the porous space within the rock has simple pore geometry, e.g., a spherical shape with a smooth surface. However, in reality, the surface of the solid-pore interface is irregular and rough. Surface roughness accelerates the relaxation of NMR signals by offering more surface area for nuclear spins to be relaxed, resulting in shorter NMR relaxation times. Without accounting for the surface roughness effect in NMR log interpretation, petrophysicists may underestimate the pore sizes of reservoir rocks. As a result there is a pressing need to develop systems and methods to determine pore surface roughness and correct NMR relaxation times.

### SUMMARY

This summary is provided to introduce a selection of concepts that are further described below in the detailed description. This summary is not intended to identify key or essential features of the claimed subject matter, nor is it intended to be used as an aid in limiting the scope of the claimed subject matter.

In general, in one aspect, embodiments related to a method for a novel three-dimensional (“3D”) pore surface roughness quantification are disclosed. The methods include obtaining, using a micro-computed tomography system, a 3D image of a pore space and, using an image analysis system: discretizing the 3D image to generate a meshed surface; constructing, using parametric functions, a reference surface and a constructed surface from the meshed surface, wherein the reference surface preserves a smoother shape of the pore space than the constructed surface; evaluating, using the reference surface and the constructed surface, a plurality of surface distances, wherein the plurality comprises a surface distance for each mesh point; and determining, using the plurality of surface distances, a roughness coefficient. The methods further include obtaining, using a nuclear magnetic resonance (“NMR”) well logging tool, an observed T2 time for at least one sample depth in a well; determining, using a well log analysis system and the roughness coefficient, a corrected T2 time from the observed T2 time; and determining, using the well log analysis system and the corrected T2 time, an average pore size in a rock formation.

In general, in one aspect, embodiments related to a system for a novel 3D pore surface roughness quantification are disclosed. The system includes a micro-computed tomography system configured to obtain a 3D image of a pore space, and an image analysis system configured to: discretize the 3D image to generate a meshed surface; construct, using parametric functions, a reference surface and a constructed surface from the meshed surface, wherein the reference surface preserves a smoother shape of the pore space than the constructed surface; evaluate, using the reference surface and the constructed surface, a plurality of surface distances, wherein the plurality comprises a surface distance for each mesh point; and determine, using the plurality of surface distances, a roughness coefficient. The system further includes a NMR well logging tool configured to obtain an observed T2 time for at least one sample depth in a well, and a well log analysis system configured to: determine, using the roughness coefficient, a corrected T2 time from the observed T2 time; and determine, using the corrected T2 time, an average pore size in a rock formation.

Other aspects and advantages of the claimed subject matter will be apparent from the following description and the appended claims.

### BRIEF DESCRIPTION OF DRAWINGS

Specific embodiments of the disclosed technology will now be described in detail with reference to the accompanying figures. Like elements in the various figures are denoted by like reference numerals for consistency.

FIG. 1 shows an NMR-logging system and associated magnetic fields, in accordance with one or more embodiments.

FIG. 2 shows a microscale rock sample, in accordance with one or more embodiments.

FIG. 3A shows the skeleton of a second-level pore separation algorithm and individual pore spaces, in accordance with one or more embodiments.

FIG. 3B shows bridging nodes, end nodes, and links, in accordance with one or more embodiments.

FIG. 3C shows a pixelated pore space before and after topology fixing, in accordance with one or more embodiments.

FIG. 4 shows a triangulated mesh of a pore space surface, in accordance with one or more embodiments.

FIG. 5 shows constructions with few and many spherical harmonic functions, in accordance with one or more embodiments.

FIG. 6 shows areas of low roughness and areas of high roughness, in accordance with one or more embodiments.

FIG. 7 shows roughness values and mesh element areas along with locations of more roughness, in accordance with one or more embodiments.

FIG. 8 shows a computer system, in accordance with one or more embodiments.

FIG. 9 shows a workflow, in accordance with one or more embodiments.

### DETAILED DESCRIPTION

In the following detailed description of embodiments of the disclosure, numerous specific details are set forth in order to provide a more thorough understanding of the disclosure. However, it will be apparent to one of ordinary skill in the art that the disclosure may be practiced without these specific details. In other instances, well-known features have not been described in detail to avoid unnecessarily complicating the description.

Throughout the application, ordinal numbers (e.g., first, second, third, etc.) may be used as an adjective for an element (i.e., any noun in the application). The use of ordinal numbers is not to imply or create any particular ordering of the elements nor to limit any element to being only a single element unless expressly disclosed, such as using the terms “before,” “after,” “single,” and other such terminology. Rather, the use of ordinal numbers is to distinguish between the elements. By way of an example, a first element is distinct from a second element, and the first element may encompass more than one element and succeed (or precede) the second element in an ordering of elements.

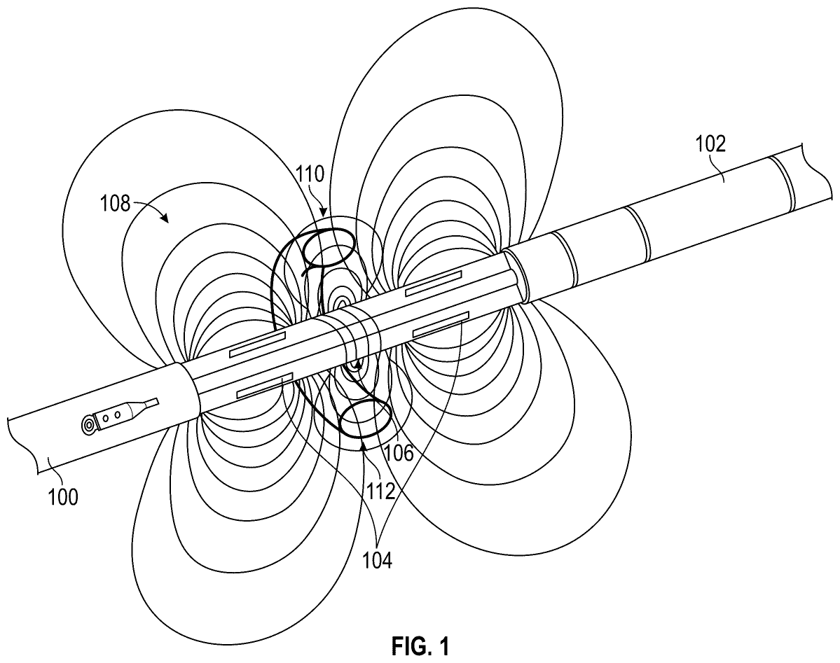

In the following description of FIGS. 1-9, any component described with regard to a figure, in various embodiments disclosed herein, may be equivalent to one or more like-named components described with regard to any other figure. For brevity, descriptions of these components will not be repeated with regard to each figure. Thus, each and every embodiment of the components of each figure is incorporated by reference and assumed to be optionally present within every other figure having one or more like-named components. Additionally, in accordance with various embodiments disclosed herein, any description of the components of a figure is to be interpreted as an optional embodiment which may be implemented in addition to, in conjunction with, or in place of the embodiments described with regard to a corresponding like-named component in any other figure.

It is to be understood that the singular forms “a,” “an,” and “the” include plural referents unless the context clearly dictates otherwise. Thus, for example, reference to “a NMR log” includes reference to one or more of such NMR logs.

Terms such as “approximately,” “substantially,” etc., mean that the recited characteristic, parameter, or value need not be achieved exactly, but that deviations or variations, including for example, tolerances, measurement error, measurement accuracy limitations and other factors known to those of skill in the art, may occur in amounts that do not preclude the effect the characteristic was intended to provide.

It is to be understood that one or more of the steps shown in the flowcharts may be omitted, repeated, and/or performed in a different order than the order shown. Accordingly, the scope disclosed herein should not be considered limited to the specific arrangement of steps shown in the flowcharts.

Although multiple dependent claims are not introduced, it would be apparent to one of ordinary skill that the subject matter of the dependent claims of one or more embodiments may be combined with other dependent claims.

Nuclear magnetic resonance (NMR) is a physical phenomenon that has been used in chemistry, physics, as well as in medicine to image opaque bodies. The same principles involved in these disciplines apply to imaging any fluid-saturated porous medium, including rocks in a hydrocarbon reservoir. NMR imaging has therefore been adapted to both laboratory research as well as borehole logging tools for in situ reservoir evaluation.

NMR-logging measures the induced magnetic moment of hydrogen nuclei (protons) contained within the fluid-filled pore spaces of reservoir rocks. Magnetic moment is the strength and direction of a magnetic field, and may be visualized as a vector-valued quantity at each point within the magnetic field. A magnetic moment may be induced by subjecting the sample to an externally generated magnetic field.

Unlike acoustic, density, neutron, resistivity, and other conventional logging measurements, which respond to rock and fluid properties, NMR-logging measurements respond to the presence of hydrogen protons. These protons primarily occur in pore fluids, hence NMR measurements are a function of the volume, composition, viscosity, and distribution of these fluids (e.g., oil, gas, and water). NMR logs provide information about the fluids present in a medium, including the sizes of the pores containing the fluids. From this information, it is possible to infer physical properties such as porosity and permeability.

There are two phases to an NMR measurement: polarization and acquisition. First, hydrogen atoms in the fluid must be aligned (polarized) in the direction of a first static external magnetic field. This polarization takes a characteristic time T1. Second, the hydrogen atoms are tipped by a short burst from a second oscillating magnetic field that is designed so that the atoms precess in resonance in a plane perpendicular to the first external magnetic field. The frequency of oscillation is known as the Larmor frequency. The precession of the hydrogen atoms induces an electrical signal in a receiving antenna. The decay time of this signal is known as the T2 time.

FIG. 1 shows an example of an NMR-logging tool (100). In this case the NMR-logging tool (100) is attached to a rotating drillstring (102). Permanent magnets (104) as well as transmitter coils (106) and receiver coils (not shown) are attached to the drillstring (102). The permanent magnets (104) create a low-gradient static magnetic field shown here by the larger equipotential curves (108). The transmitter coils (106) create the second short-burst oscillating magnetic field shown by the smaller equipotential curves (110) and the half-donut-shape (112) that lies closer to the transmitter coils (106).

During well logging, there is a tradeoff between the time needed for polarization and acquisition and other logging parameters such as logging speed and sampling frequency. The longer the time spent on polarization and acquisition, the more complete the measurement. However, a long polarization and acquisition time will result in a slower logging speed or less frequent samples.

One of the important applications of NMR well logging is to evaluate the pore size distribution by assuming the pore space has a simple geometry, e.g., a spherical shape with a smooth surface. However, the solid-pore interface may be irregular and rough. This roughness accelerates the relaxation of NMR signals by offering more surface area for nuclear spins to be relaxed, resulting in a shorter T2 time. Without accounting for the surface roughness in NMR-logging interpretation, petrophysicists may underestimate the pore sizes within reservoir rocks.

Presented below are methods and a system for determining the surface roughness of pore spaces in rocks so that the pore size may be accurately estimated. The T2 time may then be corrected. Determination of surface roughness is accomplished by obtaining an image of a connected volume of pore spaces, examining a pixelated (i.e., discretized) version of the image of a particular three-dimensional (“3D”) pore space, and constructing a triangulated mesh surface in place of the original pixelated pore space. A reference surface without surface texture may be created using parametric functions (such as, e.g., spherical harmonic functions), and a constructed surface that includes surface roughness may also be generated. The height variation between the reference and constructed surface may then be calculated as a surface roughness value at each location on the surface and used to determine a roughness coefficient that represents the entire pore space. This roughness coefficient may then be used to correct the T2 time.

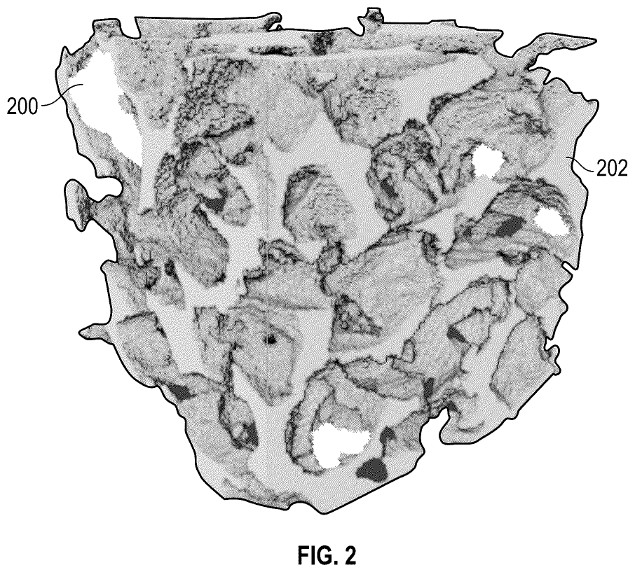

FIG. 2 shows a pixelated 3D image of pore space (200) and rock matrix (202) in a rock sample obtained from a micro-computed tomography system and imaged by an image analysis system. However, other image types may be used to obtain a 3D pixelated image, such as, e.g., micro-CT, nano-CT, etc. The 3D image may also be a 3D pixel representation of an x-ray of a rock sample. Methods that create synthetic pore structures may also be used, including stochastic methods, process-based methods, and deep learning methods. The 3D image may be segmented, for example by converting it into a binary image that interprets each pixel as either rock matrix (the binary 1) or pore space (the binary 0). After the grayscale image has been segmented into a binary image, the three-dimensional pore space will be partitioned into a plurality of individual pores using a marker-controlled watershed segmentation method. However, other methods known to a person of ordinary skill in the art may be used instead of the watershed method.

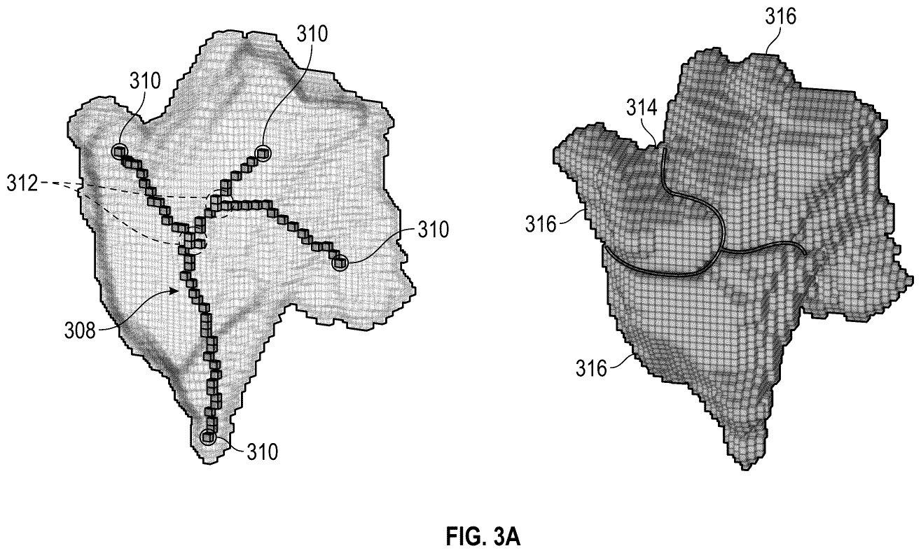

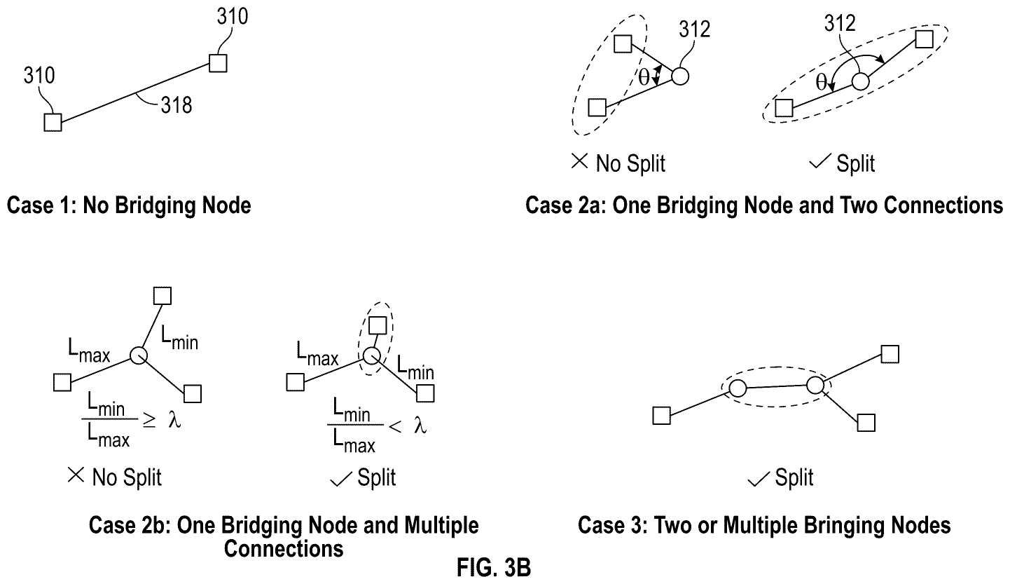

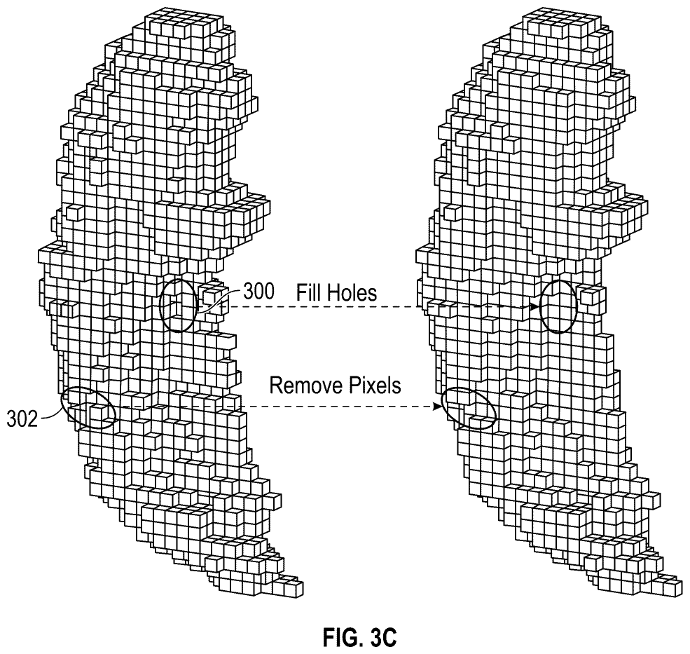

Some disconnected pore bodies among the plurality of individual pores may have complex geometries, which are not suitable for a spherical harmonic expansion (e.g., they may have handles). Thus, a second-level pore separation algorithm may be used to simplify the pore geometry of the disconnected pore bodies further. As shown in FIG. 3A, the second-level pore separation algorithm creates a “pore skeleton” (308) along the medial axis through a 3D binary volume of the pore space. The pore skeleton (308) is saved as a network graph (nodes and connections). The nodes are classified into two categories, either an endpoint node (310) or a bridging node (312), depending on how it links with other nodes. The endpoint node (310) has a single link (318) with its neighboring node, while the bridging node (312) connects two or multiple nodes. The connections include the pairs of connected nodes and all the pixels that constitute the link (318) between these two nodes. Following FIG. 3B, the extracted skeleton may then be broken up based on the following rules: 1) The link remains intact if there is no bridging node (312) between endpoint nodes (310), and the pore body will not be divided. (Case 1 of FIG. 3B.) 2) When there is one and only one bridging node (312) present, the skeleton breakup algorithm has two branches in terms of the number of endpoint nodes (310). If there are two endpoints nodes (310) (in other words, two links), the bridging node (312) will be removed from the skeleton only if they were sufficiently separated. This is controlled by comparing the included angle between links (318) with a user-defined parameter, θ. (Case 2A of FIG. 3B.) If there are multiple endpoint nodes (310), the shortest link will be removed from the skeleton if its length was much smaller than the longest one. (Case 2B of FIG. 3B.) Similar to the previous situation, users may specify a threshold value, A, as the ratio of the length of the shortest link to the length of the longest link, to control the removal of the shortest link. The default values of 0 and A are set to 120° and 0.3, respectively, in this embodiment but may be assigned different values in other situations. 3) When there are two or multiple bridging nodes (312), the graph theory may be utilized to assist in finding the longest path on which two endpoint nodes (310) are separated furthest. The shortest link between the bridging nodes (312) can be removed as a simple solution (Case 3 of FIG. 3B.), but a more sophisticated link selection process can also be applied. Following the above procedures, the remaining nodes of the skeleton may be used as markers for watershed segmentation to automate the second-level pore separation if necessary. After implementation, the second-level pore separation algorithm determines curves (314) that separate individual pore spaces (316), (see FIG. 3A). The generated individual pore spaces (316) may then used in the following steps to determine pore roughness.

Topology fixing and surface re-meshing are necessary prior to surface reconstruction of an individual pore. Topology fixing attempts to fill pixel vacancies and remove unnecessary pixels from the pore surface so that the surface has a spherical topology. A surface has spherical topology if the surface meets the requirements of being closed and having no holes and handles. The fixed pore surface with a spherical topology may be mapped to a unit spherical surface, from which spherical harmonic coefficients for surface reconstruction may be calculated. It is intended that topology fixing not change the original pore volume significantly. FIG. 3C shows topology fixing applied to a pixelated pore structure by filling a hole (300) and removing several unnecessary pixels (302). Such changes enable the pixelated model to reach the spherical topology requirement, i.e., that the model is closed, no internal boundaries, and no holes within it. A nonlinear mapping is created between the pore surface and the parametric surface (i.e., the spherical surface with radius of 1). This is critical to control area and length distortions when mapping the vertices on the pore surface to the spherical surface in the spherical parameterization.

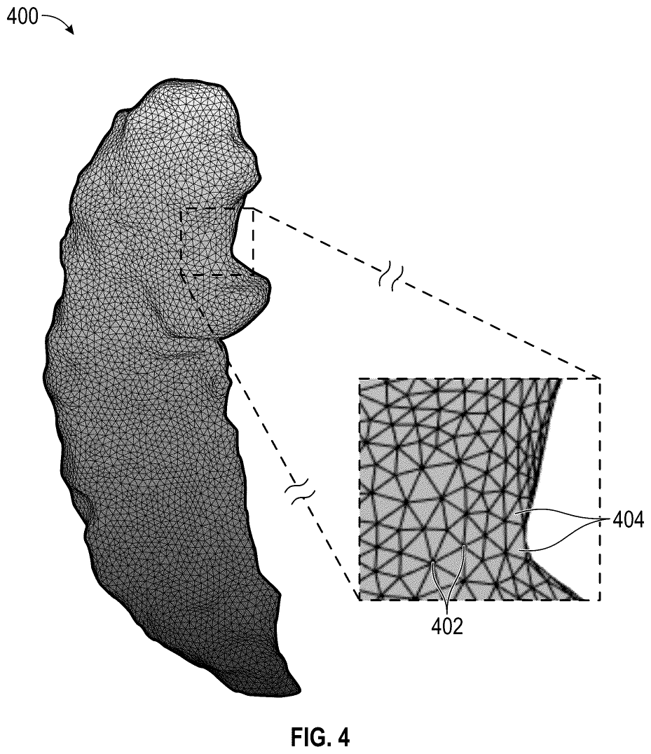

Once the topology fixing is done, the surface of the pixelated pore structure may be recreated using a triangulated mesh (400), as shown in FIG. 4. The mesh includes mesh points (402) and mesh elements (404). The coordinates of the mesh points (402) (i.e., the x-, y-, and z-coordinates of each vertex in the mesh) are the inputs to the spherical parameterization. The number of mesh points (402) in the mesh controls the computational efficiency. Typically, a finer triangulated mesh (400) increases the computational cost but brings a higher reconstruction accuracy of finer surface texture. The triangulated mesh (400) may be produced by any meshing algorithm that may be known to a person of ordinary skill in the art.

Once the triangulated mesh (400) is recreated, a surface may be constructed using two mathematical tools: spherical parameterization and spherical harmonics. Spherical parameterization is a prerequisite for deriving a spherical harmonic [SH] expansion, and creates a one-to-one mapping between a given pore surface and a unit spherical surface such that

$${( x ( θ , φ , 1 ) , y ( θ , φ , 1 ) , z ( θ , φ , 1 ) )}^{T} = p ( θ , φ , 1 ) \qquad ( 1 )$$

where x, y, and z are the coordinates of a mesh point (402) on the object surface. p(θ,φ,1) is the corresponding point on the unit spherical surface, with the azimuth angle φ and the inclination angle θ ranging from [0, 2π] and [0, π] respectively. The unit radius may be ignored in the following formulations.

Spherical parameterization is a particular case of surface parameterization. In surface parametrization a one-to-one mapping may be created from some parameter domain to a surface. The parameter domain may be itself a surface, and thus surface parametrization may include mapping one surface S1 to another surface S2. In the case of spherical parametrization, the parameter domain is the surface of a unit sphere.

In some embodiments, surface parametrization involves the minimization of some types of distortions, such as, for example, length distortion, angle distortion, and area distortion. Accordingly, a surface parametrization may be isometric, or length preserving, if each arc on surface S1 is mapped to an arc on surface S2 with the same length. In addition, a surface parametrization may be conformal, or angle preserving, if the angle of each pair of intersecting arcs on surface S2 is the same as that of the corresponding arc pair on surface S1. A surface parametrization may be also equiareal, or area preserving, if each part on S1 is mapped onto a part on S2 with the same area. One skilled in the art would understand that surface parametrization may be one of, or a combination of two or three of, isometric, conformal and equiareal.

In some embodiments, the spherical parametrization may be performed using a Control of Area and Length Distortion (CALD) algorithm. However, any other method for spherical parametrization known to a person of ordinary skill in the art may also be used. The CALD algorithm minimizes the area distortion while controlling the length distortion. The CALD algorithm may start with an initial parametrization and may improve iteratively the quality of a mesh for better parametrization. In some embodiments the iterative procedure is based on mesh smoothing. Mesh smoothing is a procedure that relocates mesh points (402) to improve the mesh quality without changing the mesh topology. Non-limiting examples of mesh-smoothing techniques include Laplacian smoothing and optimization-based smoothing. In some embodiments, local smoothing and global smoothing are combined to improve the quality of the mesh. Local smoothing aims at minimizing area distortion at a local sub-mesh, while global smoothing aims at distributing area distortion over the whole surface.

Once spherical parametrization is performed on the triangulated mesh (400), a surface may be obtained in continuous form using series expansions with spherical harmonics (SH). Specifically, any point coordinate (x(θ′,φ′), y (θ′,φ′),z (θ′, φ′))^{T} on the pore surface can be expanded as a summation of SH series

$$x ( {θ}^{′} , {φ}^{′} ) = {\sum }_{n = 0}^{N} {\sum }_{m = - n}^{n} {c}_{x n}^{m} {Y}_{n}^{m} ( {θ}^{′} , {φ}^{′} ) \qquad ( 2 )$$

$$y ( {θ}^{′} , {φ}^{′} ) = {\sum }_{n = 0}^{N} {\sum }_{m = - n}^{n} {c}_{yn}^{m} {Y}_{n}^{m} ( {θ}^{′} , {φ}^{′} ) \qquad ( 3 )$$

$$z ( {θ}^{′} , {φ}^{′} ) = {\sum }_{n = 0}^{N} {\sum }_{m = - n}^{n} {c}_{zn}^{m} {Y}_{n}^{m} ( {θ}^{′} , {φ}^{′} ) \qquad ( 4 )$$

where N is the total degree and m is the order of SH series. The real form of the SH function Yₙ^{m}(θ′,φ′) is given by

$${Y}_{n}^{m} ( {θ}^{′} , {φ}^{′} ) = \{ \begin{matrix}\sqrt{\frac{( 2 n + 1 ) ( n - m ) !}{4 π ( n + m ) !}} {P}_{n}^{m} ( cos {θ}^{′} ) cos ( m {φ}^{′} ) , m \geq 0 \\ \sqrt{\frac{( 2 n + 1 ) ( n - \vert m \vert ) !}{4 π ( n + \vert m \vert ) !}} {P}_{n}^{\vert m \vert} ( cos {θ}^{′} ) cos ( \vert m \vert {φ}^{′} ) , m < 0\end{matrix} \qquad ( 5 )$$

where pₙ^{m} is the associated Legendre function

$${P}_{n}^{m} = {( - 1 )}^{m} ( 1 - {x}^{2} ) \frac{{d}^{m}}{d {x}^{m}} [ \frac{1}{{2}^{n} n !} \frac{{d}^{n}}{d {x}^{n}} {( {x}^{2} - 1 )}^{n} ] \qquad ( 6 )$$

The SH expansion coefficients Cₓₙ^{m}, C_{yn}^{m}, and C_{zn}^{m} are solved from the linear equation system constituted by Eq. (2)-(4). As long as the number of mesh points (402) is larger than the number of unknowns (the SH expansion coefficients) the standard least squares algorithm is sufficient to solve Cₓₙ^{m}, C_{yn}^{m}, and C_{zn}^{m}. Once the SH coefficients are calculated, one may use them to construct the pore surface.

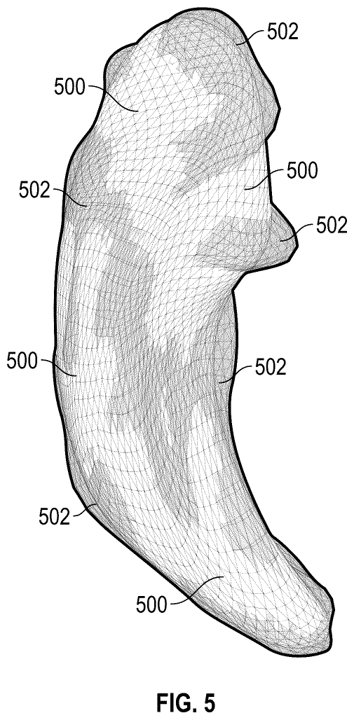

In FIG. 5, the triangulated mesh (400) with non-shaded faces (500) represents a reference surface created with the series of SH functions with a total degree N=5. This smoother surface preserves the basic pore shape but not the rough textures, and may be used as the reference surface for quantifying the roughness of the pore space, below. The area of the triangulated mesh (400) with gray-shaded faces (502) are produced with a series of SH functions with a total degree N=25; in this case this constructed surface preserves rougher textures. It is desired that the enclosed volume of both the constructed surface and the reference surface honor the same volume prior to the evaluation of surface roughness. As seen in FIG. 5, reference-surface mesh points and constructed-surface mesh points may not coincide. Similarly, reference-surface mesh elements may not coincide with constructed-surface mesh elements.

To evaluate the roughness of the pore space, vectors normal to the reference surface and passing though the reference-surface mesh points may be first determined. Then intersection points on the constructed surface may be identified, where an intersection point is the point where a normal vector of the reference surface intersects the nearest constructed-surface mesh element. From this, a distance may be computed between the intersection point on the constructed surface and the corresponding reference-surface mesh point; this distance may be treated as a surface height difference, and thus, as a measure of local roughness.

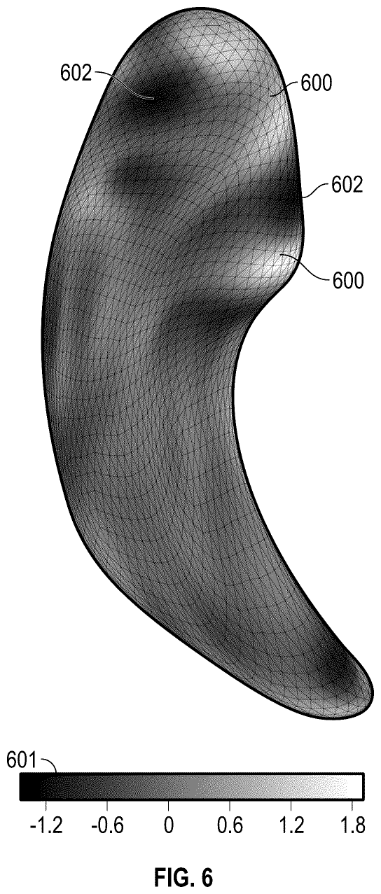

FIG. 6 shows the local roughness distribution over the reference surface of FIG. 5. The scalebar (601) indicates the surface height difference between the constructed surface and the reference surface. The distribution of the surface height difference over the reference surface shown in FIG. 6 is obtained by interpolating surface height differences among the reference-surface mesh points. Lighter shaded areas (600) correspond to locations where the constructed surface bulges out from the reference surface. Darker shaded areas (602) correspond to locations where the constructed surface bends in from the reference surface.

After determining the local roughness, a value may be determined that parameterizes the surface roughness of the entire pore space as a dimensionless value. This overall surface roughness coefficient, is evaluated by

$$α = \frac{1}{{λ}_{resol}} ( \frac{{Σ}_{i} {r}_{i} {a}_{i}}{{Σ}_{i} {a}_{i}} ) \qquad ( 7 )$$

where rᵢ and aᵢ are, respectively, the surface distance (or local roughness) of the i-th reference-surface mesh element and the area of i-th reference-surface mesh element, and λᵣₑₛₒₗ is the image resolution.

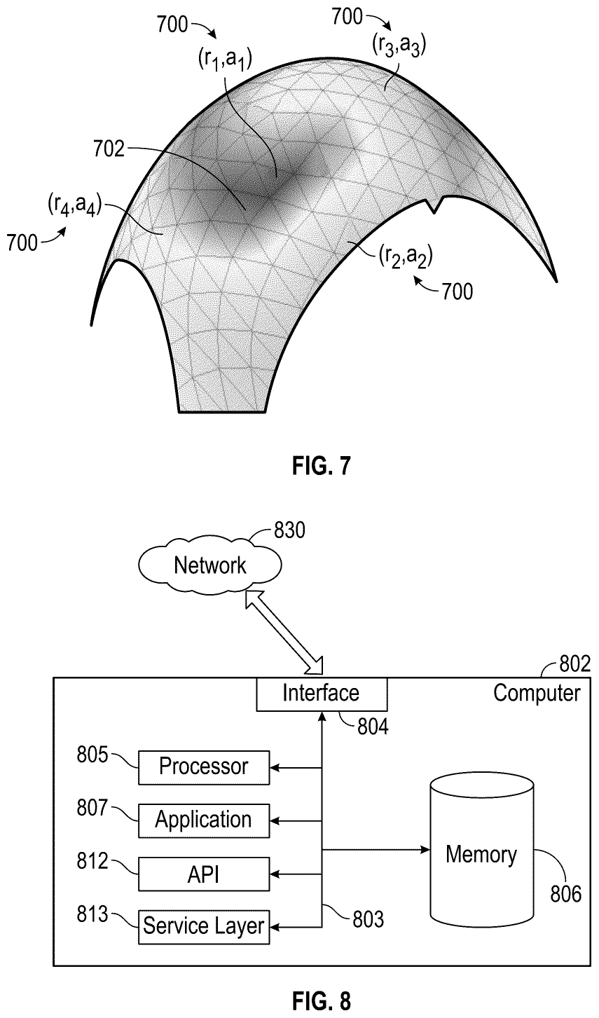

FIG. 7 labels the local-roughness measures and areas (700) of several reference-surface mesh elements. A second darker shaded area (702) represents an area of more local roughness as measured by Eq. 7.

An NMR well logging tool may be used to measure an observed T2 time for at least one depth in a well. A well log analysis system may then use a surface roughness coefficient α and the observed T2 time to determine a corrected T2 time. In some embodiments, the ratio of pore surface area to pore volume S/V of a reference pore system may be related to T2 by the expression:

$$\frac{1}{{T}_{2}^{*}} = {ρ}_{2} \frac{S}{V} \qquad ( 8 )$$

where ρ₂ is the surface relaxivity. The corrected value of T2, denoted by T₂*, may then be obtained by using the surface roughness coefficient α and the relation:

$$\frac{1}{{T}_{2}^{*}} = \frac{α}{{T}_{2}} \qquad ( 9 )$$

The well log analysis system may also use the corrected T2 time to determine an average pore size in a rock formation using techniques familiar to a person of ordinary skill in the art. The average pore size in a rock formation may subsequently be used to increase the reliability of characterizing petrophysical properties of reservoir rocks, including porosity, pore-size distribution, fluid type, permeability, etc. These reservoir characteristics may allow for the simulation, using a reservoir simulator, of fluid flow in a reservoir. The image analysis system used to obtain the 3D image of the pore spaces is a particular example of a computer system (802). A well log analysis system is another example of a computer system (802). FIG. 8 depicts a block diagram of these and other computer systems (802) used to provide computational functionalities associated with described algorithms, methods, functions, processes, flows, and procedures as described in this disclosure, according to one or more embodiments. The illustrated computer (802) is intended to encompass any computing device such as a server, desktop computer, laptop/notebook computer, wireless data port, smart phone, personal data assistant (PDA), tablet computing device, one or more processors within these devices, or any other suitable processing device, including both physical or virtual instances (or both) of the computing device. Additionally, the computer (802) may include an input device, such as a keypad, keyboard, touch screen, or other device that can accept user information, and an output device that conveys information associated with the operation of the computer (802), including digital data, visual, or audio information (or a combination of information), or a GUI.

The computer (802) can serve in a role as a client, network component, a server, a database or other persistency, or any other component (or a combination of roles) of a computer system for performing the subject matter described in the instant disclosure. The illustrated computer (802) is communicably coupled with a network (830). In some implementations, one or more components of the computer (802) may be configured to operate within environments, including cloud-computing-based, local, global, or other environment (or a combination of environments).

At a high level, the computer (802) is an electronic computing device operable to receive, transmit, process, store, or manage data and information associated with the described subject matter. According to some implementations, the computer (802) may also include or be communicably coupled with an application server, e-mail server, web server, caching server, streaming data server, business intelligence (BI) server, or other server (or a combination of servers).

The computer (802) can receive requests over network (830) from a client application (for example, executing on another computer (802)) and responding to the received requests by processing the said requests in an appropriate software application. In addition, requests may also be sent to the computer (802) from internal users (for example, from a command console or by other appropriate access method), external or third-parties, other automated applications, as well as any other appropriate entities, individuals, systems, or computers.

Each of the components of the computer (802) can communicate using a system bus (803). In some implementations, any or all of the components of the computer (802), both hardware or software (or a combination of hardware and software), may interface with each other or the interface (804) (or a combination of both) over the system bus (803) using an application programming interface (API) (812) or a service layer (813) (or a combination of the API (812) and service layer (813)). The API (812) may include specifications for routines, data structures, and object classes. The API (812) may be either computer-language independent or dependent and refer to a complete interface, a single function, or even a set of APIs. The service layer (813) provides software services to the computer (802) or other components (whether or not illustrated) that are communicably coupled to the computer (802). The functionality of the computer (802) may be accessible for all service consumers using this service layer. Software services, such as those provided by the service layer (813), provide reusable, defined business functionalities through a defined interface. For example, the interface may be software written in JAVA, C++, or other suitable language providing data in extensible markup language (XML) format or another suitable format. While illustrated as an integrated component of the computer (802), alternative implementations may illustrate the API (812) or the service layer (813) as stand-alone components in relation to other components of the computer (802) or other components (whether or not illustrated) that are communicably coupled to the computer (802). Moreover, any or all parts of the API (812) or the service layer (813) may be implemented as child or sub-modules of another software module, enterprise application, or hardware module without departing from the scope of this disclosure.

The computer (802) includes an interface (804). Although illustrated as a single interface (804) in FIG. 8, two or more interfaces (804) may be used according to particular needs, desires, or particular implementations of the computer (802). The interface (804) is used by the computer (802) for communicating with other systems in a distributed environment that are connected to the network (830). Generally, the interface (804) includes logic encoded in software or hardware (or a combination of software and hardware) and operable to communicate with the network (830). More specifically, the interface (804) may include software supporting one or more communication protocols associated with communications such that the network (830) or interface's hardware is operable to communicate physical signals within and outside of the illustrated computer (802).

The computer (802) includes at least one computer processor (805). Although illustrated as a single computer processor (805) in FIG. 8, two or more processors may be used according to particular needs, desires, or particular implementations of the computer (802). Generally, the computer processor (805) executes instructions and manipulates data to perform the operations of the computer (802) and any algorithms, methods, functions, processes, flows, and procedures as described in the instant disclosure.

The computer (802) also includes a memory (806) that holds data for the computer (802) or other components (or a combination of both) that can be connected to the network (830). For example, memory (806) can be a database storing data consistent with this disclosure. Although illustrated as a single memory (806) in FIG. 8, two or more memories may be used according to particular needs, desires, or particular implementations of the computer (802) and the described functionality. While memory (806) is illustrated as an integral component of the computer (802), in alternative implementations, memory (806) can be external to the computer (802).

The application (807) is an algorithmic software engine providing functionality according to particular needs, desires, or particular implementations of the computer (802), particularly with respect to functionality described in this disclosure. For example, application (807) can serve as one or more components, modules, applications, etc. Further, although illustrated as a single application (807), the application (807) may be implemented as multiple applications (807) on the computer (802). In addition, although illustrated as integral to the computer (802), in alternative implementations, the application (807) can be external to the computer (802).

There may be any number of computers (802) associated with, or external to, a computer system containing computer (802), wherein each computer (802) communicates over network (830). Further, the term “client,” “user,” and other appropriate terminology may be used interchangeably as appropriate without departing from the scope of this disclosure. Moreover, this disclosure contemplates that many users may use one computer (802), or that one user may use multiple computers (802).

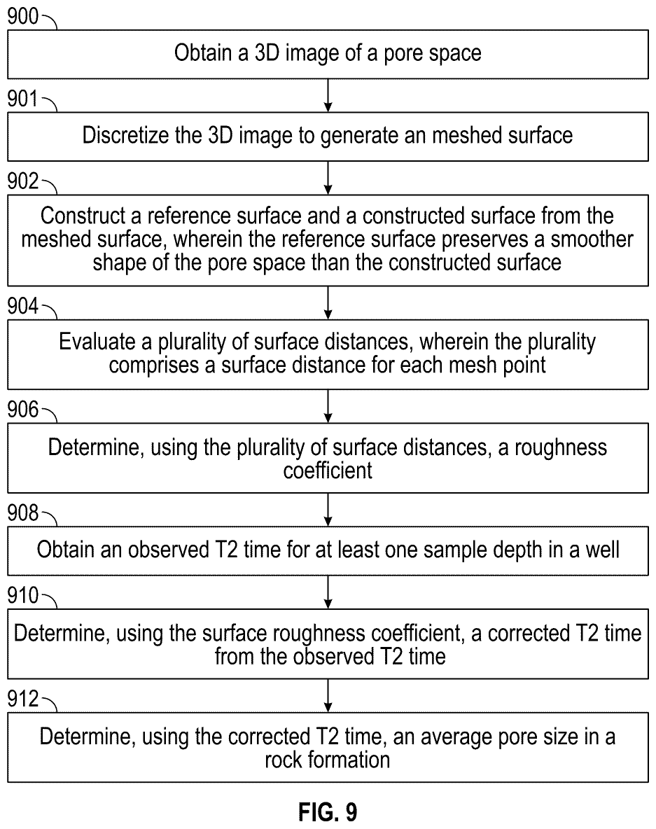

FIG. 9 presents an example of a workflow of the method described above, in accordance with one or more embodiments. In Step 900, a 3D image of a pore space is obtained using a micro-computed tomography system. The 3D image may be produced by a u-CT scanner. Steps 901, 902, 904, and 906 all require the use of an image analysis system. In Step 901, the 3D image is discretized to generate a meshed surface. The discretization process may involve segmenting the image such that each pixel of the image is given a binary classification. Topology fixing may be also performed in this step, where unnecessary pixels are removed and pixel vacancies are filled. The mesh (400) may use triangulated mesh elements (404). In Step 902, a reference surface and a constructed surface are constructed, using parametric functions, from the meshed surface, wherein the reference surface preserves a smoother shape of the pore space than the constructed surface. The parametric functions may be spherical harmonic functions. The reference surface may be constructed using the control of area and length distortion algorithm (CALD) algorithm. In Step 904, a plurality of surface distances are evaluated, using the reference surface and the constructed surface, wherein the plurality comprises a surface distance for each mesh point (402). The surface distances may be height differences between the constructed surface and the reference surface such that the height is measured in a direction normal to the reference surface. In Step 906, a roughness coefficient is determined, using the plurality of surface distances. The roughness coefficient may be determined by Equation 7. In Step 908 an observed T2 time is obtained for at least one sample depth in a well, using a nuclear magnetic resonance (“NMR”) well logging tool. In Step 910, a corrected T2 time is determined from the observed T2 time, using a well log analysis system and the roughness coefficient. In Step 912, an average pore size is determined in a rock formation, using the well log analysis system and the corrected T2 time. The average pore size may be used in a reservoir fluid simulation, the selection of a drilling target, the planning of a well trajectory, and the drilling a borehole. The drilled borehole may be guided by the planned well trajectory to penetrate the drilling target.

Although only a few example embodiments have been described in detail above, those skilled in the art will readily appreciate that many modifications are possible in the example embodiments without materially departing from this invention. Accordingly, all such modifications are intended to be included within the scope of this disclosure as defined in the following claims.

What is claimed is:

1. A method, comprising:
obtaining, using a micro-computed tomography system, a three-dimensional (“3D”) image of a pore space;
using an image analysis system:
discretizing the 3D image to generate a meshed surface,
constructing, using parametric functions, a reference surface and a constructed surface from the meshed surface, wherein the reference surface preserves a smoother shape of the pore space than the constructed surface,
evaluating, using the reference surface and the constructed surface, a plurality of surface distances, wherein the plurality comprises a surface distance for each mesh point, and
determining, using the plurality of surface distances, a roughness coefficient;
obtaining, using a nuclear magnetic resonance (“NMR”) well logging tool, an observed T2 time for at least one sample depth in a well;
determining, using a well log analysis system and the roughness coefficient, a corrected T2 time from the observed T2 time; and
determining, using the well log analysis system and the corrected T2 time, an average pore size in a rock formation.

2. The method of claim 1, further comprising using the determined average pore size to perform the following:
simulate, using a reservoir simulator, a reservoir simulation;
select a drilling target based, at least in part, on the reservoir simulation; and
plan, using a well planning system, a planned well trajectory to penetrate the drilling target.

3. The method of claim 2, further comprising using the determined average pore size to drill, using a drilling system, a borehole guided by the planned well trajectory.

4. The method of claim 1, wherein discretizing the 3D image comprises converting the 3D image into a binary image.

5. The method of claim 1, wherein discretizing the 3D image comprises a marker-controlled watershed segmentation.

6. The method of claim 4, wherein discretizing the 3D image further comprises fixing a topology of the binary image by filling holes and removing pixels.

7. The method of claim 1, wherein evaluating the plurality of surface distances comprises determining a plurality of height differences between the constructed surface and the reference surface.

8. The method of claim 1, wherein the parametric functions are spherical harmonic functions.

9. The method of claim 1, wherein constructing the constructed surface further comprises using a control of area and length distortion algorithm (CALD).

10. The method of claim 1, further comprising using a second-level pore separation algorithm to simplify a pore space.

11. A system, comprising:
a micro-computed tomography system configured to obtain a three-dimensional (“3D”) image of a pore space;
an image analysis system configured to:
discretize the 3D image to generate a meshed surface,
construct, using parametric functions, a reference surface and a constructed surface from the meshed surface, wherein the reference surface preserves a smoother shape of the pore space than the constructed surface,
evaluate, using the reference surface and the constructed surface, a plurality of surface distances, wherein the plurality comprises a surface distance for each mesh point, and
determine, using the plurality of surface distances, a roughness coefficient;
a nuclear magnetic resonance (“NMR”) well logging tool configured to obtain an observed T2 time for at least one sample depth in a well; and
a well log analysis system configured to:
determine, using the roughness coefficient, a corrected T2 time from the observed T2 time, and
determine, using the corrected T2 time, an average pore size in a rock formation.

12. The system of claim 11, further comprising a reservoir simulator configured to:
simulate a reservoir simulation using the determined average pore size, and
select a drilling target based, at least in part, on the reservoir simulation.

13. The system of claim 12, further comprising:
a well planning system configured to plan a planned well trajectory to penetrate the drilling target; and
a drilling system configured to drill a borehole guided by the planned well trajectory.

14. The system of claim 11, wherein the image analysis system is further configured to convert the 3D image into a binary image.

15. The system of claim 11, wherein the image analysis system is further configured to perform a marker-controlled watershed segmentation.

16. The system of claim 14, wherein the image analysis system is further configured to fix a topology of the binary image by filling holes and removing pixels.

17. The system of claim 11, wherein the image analysis system is further configured to determine a plurality of height differences between the constructed surface and the reference surface.

18. The system of claim 11, wherein the parametric functions are spherical harmonic functions.

19. The system of claim 11, wherein the image analysis system is further configured to construct the constructed surface using a control of area and length distortion algorithm (CALD).

20. The system of claim 11, further comprising a second-level pore separation algorithm configured to simplify a pore space.
